(19) United States
(12) Patent Application Publication
(10) Pub. No.: US 2026/0020230 A1
(43) Pub. Date: Jan. 15, 2026

(54) SEMICONDUCTOR MEMORY DEVICE AND METHOD FOR MANUFACTURING THE SAME

(71) Applicant: Samsung Electronics Co., Ltd., Suwon-si (KR)

(72) Inventors: Seong Tak CHO, Suwon-si (KR); Kyu Hyun LEE, Suwon-si (KR); Sang Ho LEE, Suwon-si (KR); Yong Kwan KIM, Suwon-si (KR); In Woo KIM, Suwon-si (KR); Hui Jung KIM, Suwon-si (KR)

(73) Assignee: Samsung Electronics Co., Ltd., Suwon-si (KR)

(21) Appl. No.: 19/214,619

(22) Filed: May 21, 2025

(30) Foreign Application Priority Data
Jul. 12, 2024 (KR) 10-2024-0092425

(51) Int. Cl. H10B 12/00; H01L 23/528; H10D 1/68

(52) U.S. Cl. CPC H10B 12/50; H01L 23/5283; H10B 12/312; H10B 12/318; H10B 12/482; H10D 1/716; H10B 12/09

(57) ABSTRACT

A semiconductor memory device includes a substrate, a capacitor structure including a lower electrode electrically connected to a storage pad, a capacitor dielectric film, and an upper electrode, a cell metal contact contacting an upper surface of the upper electrode, a first peripheral contact plug electrically connected to the substrate, a first peripheral wiring pad in a first interlayer insulating film on the storage pad, a second peripheral contact plug electrically connected to the first peripheral wiring pad, a second peripheral wiring pad contacting the second peripheral contact plug, and a peripheral metal contact electrically connected to the second peripheral wiring pad, wherein a vertical surface of the second peripheral wiring pad is at a level of the upper surface of the upper electrode, and a bottom surface level of the capacitor structure is at a vertical level of an upper surface of the first peripheral wiring pad.

### CROSS-REFERENCE TO RELATED APPLICATION

This application claims priority from Korean Patent Application No. 10-2024-0092425 filed on Jul. 12, 2024 in the Korean Intellectual Property Office, and all the benefits accruing therefrom under 35 U.S.C. 119, the contents of which are herein incorporated by reference in their entirety.

### BACKGROUND

### Field

The inventive concepts relate to a semiconductor memory device and/or a method for manufacturing the same.

### Description of Related Art

A semiconductor memory device has an increasingly higher integration level. Thus, in order to implement more semiconductor elements in the same area, individual circuit patterns are increasingly smaller. In other words, as the integration level of the semiconductor memory device increases, a design rule for components of the semiconductor memory device is decreases. A design rule may be, for example, a maximum spacing between word lines.

Accordingly, it is difficult to ensure reliability of the semiconductor memory device.

### SUMMARY

Some example embodiments of the inventive concepts provide a semiconductor memory device that may have improved reliability and performance.

Some example embodiments in accordance with the inventive concepts are not limited to the above-mentioned example embodiments. Other example embodiments and advantages in accordance with the inventive concepts as not mentioned above may be understood from following descriptions and more clearly understood from some example embodiments in accordance with the inventive concepts. Further, it will be readily appreciated that some example embodiments and advantages in accordance with the inventive concepts may be realized by features and combinations thereof as disclosed in the claims.

According to some example embodiments, a semiconductor memory device includes a substrate extending in first and second directions intersecting each other, the substrate including a cell area and a peripheral area around the cell area, a storage pad on the cell area, a capacitor structure including a lower electrode electrically connected to the storage pad, a capacitor dielectric film extending along the lower electrode, and an upper electrode on the capacitor dielectric film, a cell metal contact on the upper electrode and contacting an upper surface of the upper electrode, a peripheral gate structure on the peripheral area, a first peripheral contact plug on at least one side of the peripheral gate structure and electrically connected to the substrate, a first peripheral wiring pad in a first interlayer insulating film on the storage pad and the first peripheral contact plug, a second peripheral contact plug extending through a second interlayer insulating film on the first interlayer insulating film in a third direction perpendicular to each of the first direction and the second direction, wherein the second peripheral contact plug is electrically connected to the first peripheral wiring pad, a second peripheral wiring pad on the second peripheral contact plug and contacting the second peripheral contact plug, and a peripheral metal contact in the third interlayer insulating film on the second peripheral wiring pad, wherein the peripheral metal contact is electrically connected to the second peripheral wiring pad, wherein in the third direction, the second peripheral wiring pad has a surface having a vertical level equal to a vertical level of the upper surface of the upper electrode, and wherein a vertical level of a bottom surface of the capacitor structure is equal to a vertical level of an upper surface of the first peripheral wiring pad.

According to some example embodiments, a semiconductor memory device includes a substrate including a cell area and a peripheral area around the cell area, wherein the cell area includes an active area defined by an element isolation film, a storage pad on the cell area and electrically connected to the active area, a capacitor structure including a lower electrode electrically connected to the storage pad, electrode support layers supporting the lower electrode, a capacitor dielectric film extending along the lower electrode, and an upper electrode on the capacitor dielectric film, a cell metal contact on the upper electrode and contacting an upper surface of the upper electrode, a peripheral gate structure on the peripheral area, a first peripheral contact plug on each of both opposing sides of the peripheral gate structure and electrically connected to the substrate, a first peripheral wiring pad in a first interlayer insulating film on the storage pad and the first peripheral contact plug, wherein a vertical level of the first peripheral wiring pad is equal to a vertical level of the storage pad, a second peripheral contact plug vertically extending through a second interlayer insulating film on the first interlayer insulating film, wherein the second peripheral contact plug is electrically connected to the first peripheral wiring pad, a second peripheral wiring pad on the second peripheral contact plug and electrically connected to the second peripheral contact plug, wherein the second peripheral wiring pad contacts an upper surface of the second interlayer insulating film, a peripheral metal contact on the second peripheral wiring pad and electrically connected to the second peripheral wiring pad, and a third interlayer insulating film on the upper electrode and the second interlayer insulating film and contacting each of the upper surface of the upper electrode and an upper surface of the second interlayer insulating film, wherein in the vertical direction, the upper surface of the upper electrode and the upper surface of the second interlayer insulating film are coplanar, wherein a distance from a lower surface of the third interlayer insulating film to an upper surface of the cell metal contact is equal to a distance from a lower surface of the third interlayer insulating film to an upper surface of the peripheral metal contact, and wherein a length of the second peripheral contact plug is larger than a length of the lower electrode.

According to some example embodiments, a semiconductor memory device includes a substrate including a cell area and a peripheral area around the cell area, wherein the cell area includes an active area defined by an element isolation film, a bit line structure on the cell area and including a cell conductive line and a cell line capping film on the cell conductive line; a cell gate electrode in the cell area of the substrate and intersecting the cell conductive line, a storage pad on a side surface of the bit line structure and on the cell area, wherein the storage pad is electrically connected to the active area, a capacitor structure including a lower electrode electrically connected to the storage pad, electrode support layers supporting the lower electrode, a capacitor dielectric film extending along the lower electrode, and an upper electrode on the capacitor dielectric film, a cell metal contact on the capacitor structure and contacting an upper surface of the upper electrode, a peripheral gate structure on the peripheral area; a first peripheral contact plug on each of opposing sides of the peripheral gate structure and electrically connected to the substrate; a first peripheral wiring pad in a first interlayer insulating film, wherein the first interlayer insulating film is on the storage pad and the first peripheral contact plug, an etch stop layer on the storage pad and the first peripheral wiring pad, a second peripheral contact plug extending in a vertical direction within a second interlayer insulating film on the etch stop layer, wherein the second peripheral contact plug is electrically connected to the first peripheral wiring pad, a second peripheral wiring pad on the second peripheral contact plug and electrically connected to the second peripheral contact plug, wherein the second peripheral wiring pad contacts an upper surface of the second interlayer insulating film, a peripheral metal contact on the second peripheral wiring pad and electrically connected to the second peripheral wiring pad, and a third interlayer insulating film on the upper electrode and the second interlayer insulating film, the third interlayer insulating film contacting each of the upper surface of the upper electrode and the upper surface of the second interlayer insulating film, wherein a distance from a lower surface of the third interlayer insulating film at the cell area to a bottom surface of the lower electrode is equal to a distance from a lower surface of the third interlayer insulating film of the peripheral area to a bottom surface of the second peripheral contact plug, wherein a distance from an upper surface of the etch stop layer of the cell area to the upper surface of the upper electrode is equal to a distance from an upper surface of the etch stop layer of at peripheral area to the upper surface of the second interlayer insulating film, and wherein in the vertical direction, the second peripheral wiring pad has a surface having a vertical level equal to a vertical level of the upper surface of the upper electrode.

The specific details of some example embodiments are included in the detailed description and drawings.

### BRIEF DESCRIPTION OF DRAWINGS

The above and other example embodiments and features of the inventive concepts will become more apparent by describing, in detail, some example embodiments thereof with reference to the attached drawings, in which:

FIG. 1 is a schematic layout diagram of a semiconductor memory device according to some example embodiments;

FIG. 2 is a schematic layout of a R1 area in FIG. 1;

FIG. 3 is a schematic layout diagram of a R2 area in FIG. 1;

FIG. 4 is a plan view illustrating a semiconductor memory device according to some example embodiments;

FIG. 5 is a cross-sectional view taken along a line A-A of FIG. 1;

FIG. 6 is a cross-sectional view taken along a line B-B of FIG. 3;

FIG. 7 is a cross-sectional view taken along a line C-C of FIG. 3;

FIG. 8 is a cross-sectional view illustrating a semiconductor memory device according to some example embodiments, and is a diagram corresponding to FIG. 5;

FIG. 9 to FIG. 14 are diagrams of intermediate structures corresponding to intermediate steps of a semiconductor memory device manufacturing method according to some example embodiments; and

FIG. 15 and FIG. 16 are diagrams of intermediate structures corresponding to intermediate steps of a semiconductor memory device manufacturing method according to some example embodiments.

### DETAILED DESCRIPTION

Although terms such as first, second, upper, and/or lower are used herein to describe various elements and/or components, these element and/or components are not limited by the terms. Rather, the terms are merely used herein to distinguish one element and/or component from another element and/or component. Therefore, that a first element and/or component as mentioned below may also be a second element and/or component within the technical spirit of the inventive concepts. Further, that a lower element and/or component as mentioned below may also be an upper element and/or component within the technical spirit of the inventive concepts.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., +10%) around the stated elements and/or properties thereof.

When the terms “about” or “substantially” are used in this specification in connection with a numerical value, it is intended that the associated numerical value include a tolerance of ±10% around the stated numerical value. When ranges are specified, the range includes all values therebetween such as increments of 0.1%. Further, regardless of whether numerical values or shapes are modified as “about” or “substantially,” it will be understood that these values and shapes should be construed as including a manufacturing or operational tolerance (e.g., ±10%) around the stated numerical values or shapes.

When an element is referred to as being “connected to” or “electrically connected to” another element, the element may be directly connected to the other element, or one or more other intervening elements may be present. For example, an element described as being “connected to” another element may be “electrically connected to” the other element. In contrast, when an element is referred to as being “directly connected to” another element there are no intervening elements present.

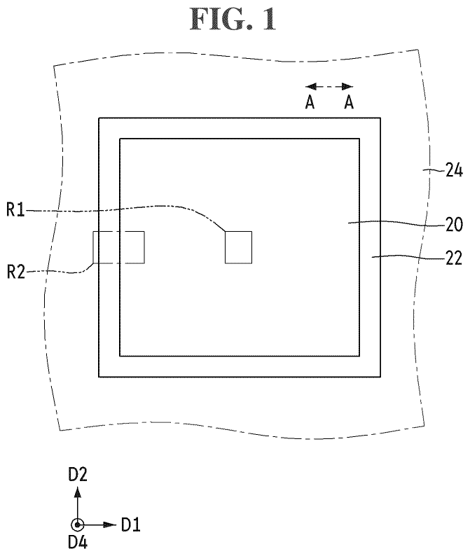

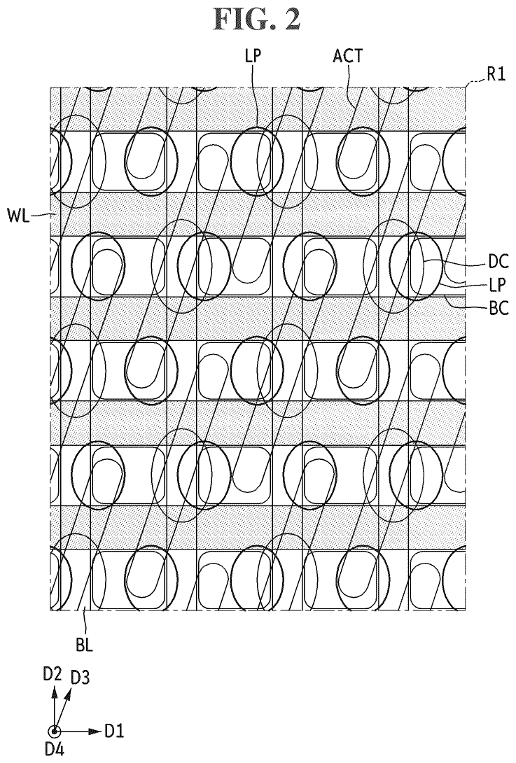

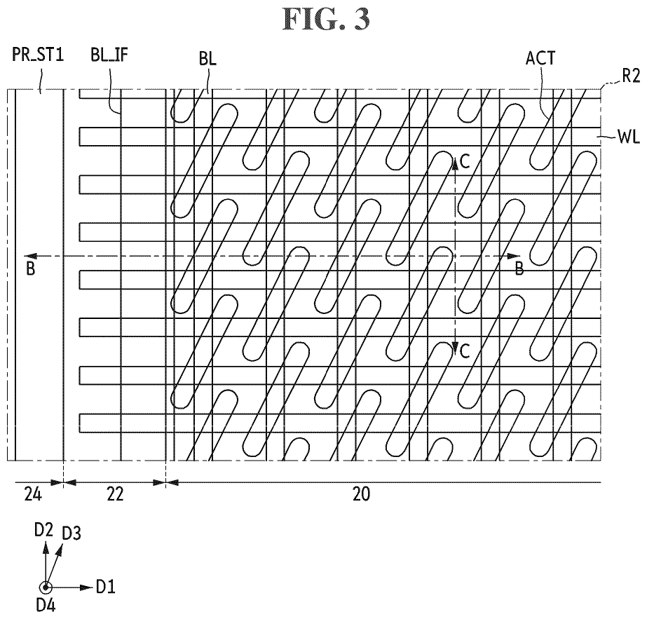

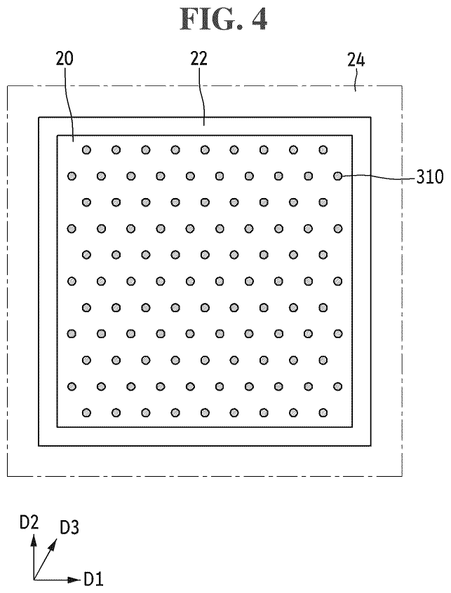

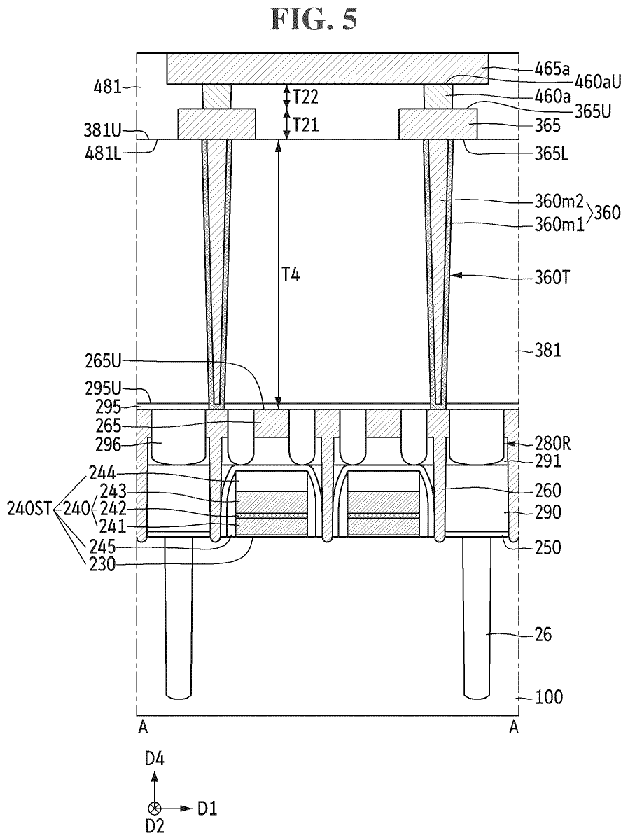

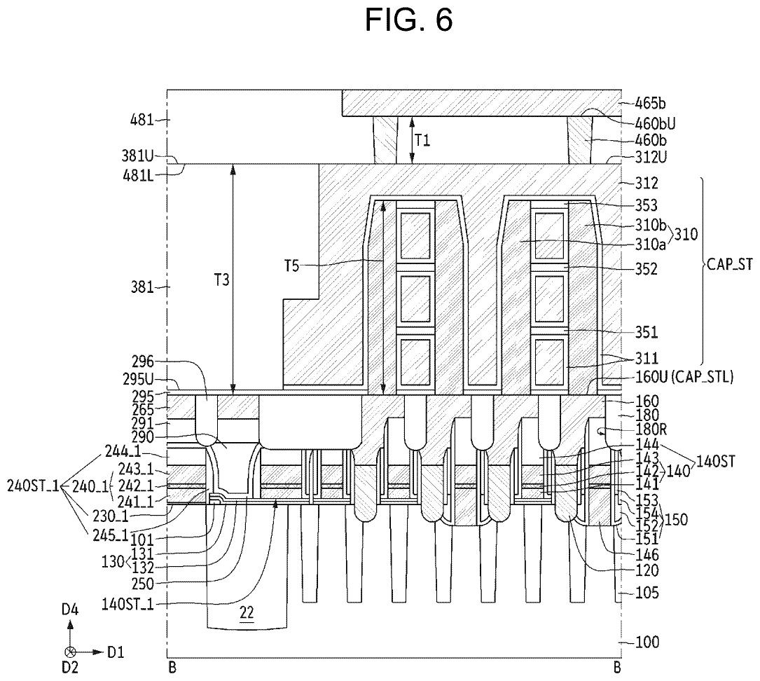

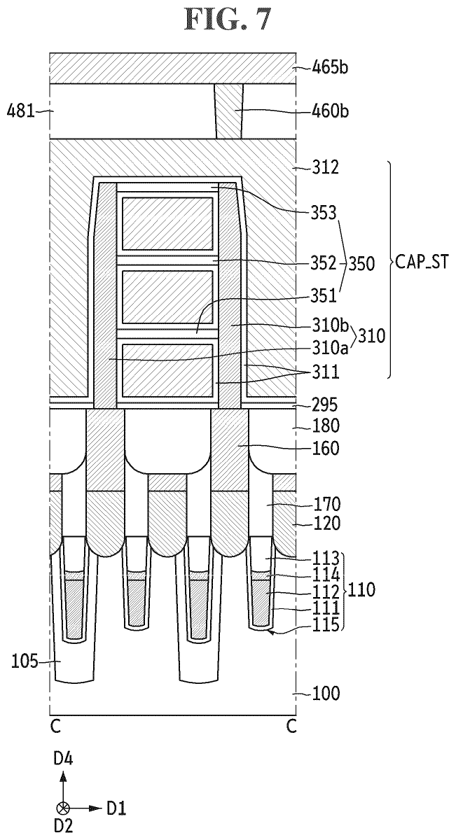

FIG. 1 is a schematic layout diagram of a semiconductor memory device according to some example embodiments. FIG. 2 is a schematic layout of a R1 area in FIG. 1. FIG. 3 is a schematic layout diagram of a R2 area in FIG. 1. FIG. 4 is a plan view illustrating a semiconductor memory device according to some example embodiments. FIG. 5 is a cross-sectional view taken along a line A-A of FIG. 1. FIG. 6 is a cross-sectional view taken along a line B-B of FIG. 3. FIG. 7 is a cross-sectional view taken along a line C-C of FIG. 3.

For reference, FIG. 5 may be an example cross-sectional view of a transistor formation area of a peripheral area.

In the drawings of a semiconductor memory device according to some example embodiments, an example in which the semiconductor memory device is embodied as a DRAM (Dynamic Random Access Memory) device is illustrated. However, the example embodiments are not limited thereto.

Referring to FIG. 1 to FIG. 3, the semiconductor memory device according to some example embodiments may include a cell area 20, a cell area isolation film 22, and/or a peripheral area 24.

The cell area isolation film 22 may be formed along a perimeter of the cell area 20. The cell area isolation film 22 may isolate the cell area 20 and the peripheral area 24 from each other. The peripheral area 24 may be defined around the cell area 20. In some example embodiments, a boundary area may mean an area on the cell area isolation film 22 and between the cell area 20 and the peripheral area 24.

The cell area 20 may include a plurality of cell active areas ACT. The cell active area ACT may be defined by a cell element isolation film (105 in FIG. 6 and FIG. 7) formed in a substrate (100 in FIG. 5 to FIG. 7). As the design rule of the semiconductor memory device decreases, the cell active area ACT may have a bar shape extending in a diagonal line or an oblique line as shown in FIG. 2. For example, the cell active area ACT may extend in a third direction D3.

Each, or one or more, of a plurality of gate electrodes may extend in a first direction D1 and across the cell active area ACT. The plurality of gate electrodes may extend parallel to each other. Each, or one or more, of the plurality of gate electrodes may be embodied as, for example, a plurality of word-lines WL. The word-lines WL may be spaced from each other by an equal spacing. A width of the word-line WL or a spacing between word-lines WL may be determined according to the design rule.

The two word-lines WLs extending in the first direction D1 may divide each cell active area ACT into three portions. The cell active area ACT may include a storage connection area and/or a bit-line connection area. The bit-line connection area may be located at a middle portion of the cell active area ACT, while the storage connection area may be located at an end of the cell active area ACT.

A plurality of bit-lines BL extending in a second direction D2 perpendicular to the extension direction of the word-line WL may be disposed on the word-lines WL. The plurality of bit-line BL may extend parallel to each other. The bit-lines BL may be arranged to be spaced from each other by the same spacing. A width of the bit-line BL or a spacing between bit-lines BLs may be determined according to the design rule.

A boundary bit-line BL_IF may extend in a second direction D2 and in a parallel manner to the bit-line BL. At least a portion of the boundary bit-line BL_IF may be disposed so as to overlap the cell area isolation film 22 in a first direction D1. Unlike what is illustrated, the semiconductor memory device according to some example embodiments may not include the boundary bit-line BL_IF.

A boundary peripheral gate PR_ST1 may extend in the second direction D2 and in a parallel manner to the boundary bit-line BL_IF. The boundary peripheral gate PR_ST1 may be disposed at a boundary between the cell area isolation film 22 and the peripheral area 24. Unlike what is illustrated, in the semiconductor memory device according to some example embodiments, the boundary peripheral gate PR_ST1 may extend in the first direction D1. Furthermore, the semiconductor memory device according to some example embodiments may not include the boundary peripheral gate PR_ST1.

A semiconductor memory device according to some example embodiments may include various contact arrangements formed on the cell active area ACT. The various contact arrangements may include, for example, a direct contact DC, a buried contact BC, and/or a landing pad LP, etc.

In this regard, the direct contact DC may mean a contact that electrically connects the cell active area ACT to the bit-line BL. The buried contact BC may mean a contact connecting the cell active area ACT to a lower electrode (310 in FIG. 6 and FIG. 7) of a capacitor structure (CAP_ST in FIG. 6 and FIG. 7). In terms of an arrangement structure, a contact area between the buried contact BC and the cell active area ACT may be small. Accordingly, a conductive landing pad LP may be introduced to expand the contact area between the cell active area ACT and the buried contact BC, and to expand the contact area between the buried contact BC and the lower electrode (310 in FIG. 6 and FIG. 7) of the capacitor structure (CAP_ST in FIG. 6 and FIG. 7).

The landing pad LP may be disposed between the cell active area ACT and the buried contact BC and may be disposed between the buried contact BC and the lower electrode (310 in FIG. 6 and FIG. 7) of the capacitor structure (CAP_ST in FIG. 6 and FIG. 7). In the semiconductor memory device according to some implementations, the landing pad LP may be disposed between the buried contact BC and the lower electrode (310 in FIG. 6 and FIG. 7) of the capacitor structure (CAP_ST in FIG. 6 and FIG. 7). Expanding the contact area via the introduction of the landing pad LP may allow a contact resistance between the cell active area ACT and the lower electrode (310 in FIG. 6 and FIG. 7) of the capacitor structure (CAP_ST in FIG. 6 and FIG. 7) to be reduced.

The direct contact DC may be connected to the bit-line connection area. The buried contact BC may be connected to the storage connection area. As the buried contact BC is dispose in each of both opposing ends of the cell active area ACT, the landing pad LP may be disposed adjacent to each of both opposing ends of the cell active area ACT and partially overlap with the buried contact BC. In other words, the buried contact BC may be formed to overlap the cell active area ACT and a cell element isolation film (105 in FIG. 5 and FIG. 6) between adjacent word-lines WL and between adjacent bit-lines BL.

The word-line WL may be formed as a structure buried in the substrate 100. The word-line WL may extend across the cell active area ACT between the direct contacts DC or between the buried contacts BC. As shown, two word-lines WL may extend through one cell active area ACT. As the cell active area ACT extends along the third direction D3, the extension direction of the word-line WL may have an angle smaller than 90 degrees with respective to the extension direction of the cell active area ACT.

The direct contacts DC and the buried contacts BC may be arranged in a symmetrical manner. Accordingly, the direct contacts DC and the buried contacts BC may be arranged in a straight line along the first direction D1 and the second direction D2. Unlike the direct contact DC and the buried contact BC, the landing pads LP may be arranged in a zigzag manner in the second direction D2 which the bit-line BL extends. Further, the landing pads LP may overlap with the same portion of a side face of each bit-line BL in the first direction D1 in which the word-line WL extends. For example, each, or one or more, of landing pads LP in a first line may overlap the left side face of a corresponding bit-line BL, while each, or one or more, of the landing pads LP in a second line may overlap with a right side face of the corresponding bit-line BL.

Referring to FIG. 1 to FIG. 7, the semiconductor memory device according to some example embodiments may include a substrate 100, a cell gate structure 110, a bit line structure 140ST, a storage pad 160, the capacitor structure CAP_ST, a cell metal contact 460b, a peripheral gate structure 240ST, a first peripheral contact plug 260, a first peripheral wiring pad 265, a second peripheral contact plug 360, a second peripheral wiring pad 365, and/or a peripheral metal contact 460a.

The substrate 100 may extend in each of the first direction D1 and the second direction D2 which intersect each other. The substrate 100 may include the cell area 20, the cell area isolation film 22, and/or the peripheral area 24. The substrate 100 may be a silicon substrate or be made of an SOI (silicon-on-insulator). Alternatively, the substrate 100 may include silicon germanium, SGOI (silicon germanium on insulator), indium antimonide, lead tellurium compound, indium arsenic, indium phosphide, gallium arsenide and/or gallium antimonide. However, the example embodiments are not limited thereto.

The plurality of cell gate structures 110, the plurality of bit-line structures 140ST, the plurality of storage pads 160, and/or the capacitor structure CAP_ST may be disposed in the cell area 20. The peripheral gate structure 240ST, the first peripheral contact plug 260, the first peripheral wiring pad 265, the second peripheral contact plug 360, and/or the second peripheral wiring pad 365 may be disposed in the peripheral area 24.

The cell element isolation film 105 may be formed in the substrate 100 and/or in the cell area 20. The cell element isolation film 105 may have an ST1 (shallow trench isolation) structure with excellent element isolation ability. The cell element isolation film 105 may define the cell active area ACT within the cell area 20. The cell active area ACT defined by the cell element isolation film 105 may have an elongated island shape including a minor axis and a major axis as shown in FIG. 2. The cell active area ACT may have a diagonal extension shape to have an angle of smaller than 90 degrees with respect to the extension direction of the word-line WL coplanar with the cell element isolation film 105. Further, the cell active area ACT may have a diagonal extension shape to have an angle of smaller than 90 degrees with respect to an extension direction of the bit-line BL formed on the cell element isolation film 105.

A cell boundary isolation film having an ST1 structure may also be formed in the cell area isolation film 22. The cell area 20 may be defined by the cell area isolation film 22.

Each, or one of more, of the cell element isolation film 105 and/or the cell area isolation film 22 may include, for example, at least one of a silicon oxide film, a silicon nitride film, and/or a silicon oxynitride film. However, the example embodiments are not limited thereto. In FIG. 6 and FIG. 7, each of the cell element isolation film 105 and the cell area isolation film 22 is shown to be formed as a single insulating film. However, this is only for convenience of illustration. However, the example embodiments are not limited thereto. Depending on a width of each of the cell element isolation film 105 and the cell area isolation film 22, each of the cell element isolation film 105 and the cell area isolation film 22 may be formed as a single insulating film, or as a stack of a plurality of insulating films.

In FIG. 6, an upper surface of the cell element isolation film 105, an upper surface of the substrate 100, and an upper surface of the cell area isolation film 22 are shown to be coplanar with each other. However, this is only for convenience of illustration. However, example embodiments are not limited thereto.

The cell gate structure 110 may be formed in the substrate 100 and/or the cell element isolation film 105. The cell gate structure 110 may be formed along the cell element isolation film 105 and the cell active area ACT defined by the cell element isolation film 105. The cell gate structure 110 may include a cell gate trench 115 formed in the substrate 100 and/or the cell element isolation film 105, a cell gate insulating film 111, a cell gate electrode 112, a cell gate capping pattern 113, and/or a cell gate capping conductive film 114. In this regard, the cell gate electrode 112 may act as the word-line WL. Unlike what is illustrated, the cell gate structure 110 may not include the cell gate capping conductive film 114.

The cell gate insulating film 111 may extend along a side wall and/or a lower surface of the cell gate trench 115. The cell gate insulating film 111 may extend along a profile of at least a portion of the cell gate trench 115. The cell gate insulating film 111 may include, for example, at least one of silicon oxide, silicon nitride, silicon oxynitride, and/or high dielectric constant material having a higher dielectric constant than that of silicon oxide. The high dielectric constant material may include, for example, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and/or combinations thereof.

The cell gate electrode 112 may be formed on the cell gate insulating film 111. The cell gate electrode 112 may fill a portion of the cell gate trench 115. The cell gate capping conductive film 114 may extend along an upper surface of the cell gate electrode 112.

The cell gate electrode 112 may include at least one of metal, metal alloy, conductive metal carbonitride, conductive metal carbide, metal silicide, doped semiconductor material, conductive metal oxynitride, and/or conductive metal oxide. The cell gate electrode 112 may include at least one of for example, (TiN), TaC, TaN, TiSiN, TaSiN, TaTiN, TiAIN, TaAIN, WN, Ru, TiAl, TiAIC-N, TiAIC, TiC, TaCN, W, Al, Cu, Co, Ti, Ta, Ni, Pt, Ni—Pt, Nb, NbN, NbC, Mo, MON, MOC, WC, Rh, Pd, Ir, Ag, Au, Zn, V, RuTiN, TiSi, TaSi, NiSi, CoSi, IrOx, RuOx, and/or combinations thereof. However, the example embodiments are not limited thereto. The cell gate capping conductive film 114 may include, for example, polysilicon or polysilicon-germanium. However, the inventive concepts are not limited thereto.

The cell gate capping pattern 113 may be disposed on the cell gate electrode 112 and/or the cell gate capping conductive film 114. The cell gate capping pattern 113 may fill a remaining portion of the cell gate trench 115 except for the cell gate electrode 112 and/or the cell gate capping conductive film 114. The cell gate insulating film 111 is shown to extend along a side wall of the cell gate capping pattern 113. However, the example embodiments are not limited thereto. The cell gate capping pattern 113 may include, for example, at least one of silicon nitride SiN, silicon oxynitride SiON, silicon oxide SiO₂, silicon carbonitride SiCN, silicon oxycarbonitride SiOCN, and/or combinations thereof.

Although not shown, an impurity doped area may be formed on at least one side of the cell gate structure 110. The impurity doped area may act as a source/drain area of the transistor.

The bit-line structure 140ST may include a cell conductive line 140 and/or a cell line capping film 144. The cell conductive line 140 may be formed on the substrate 100 including the cell gate structure 110, and/or on the cell element isolation film 105 formed in the substrate 100. The cell conductive line 140 may intersect a cell element isolation film 105, and the cell active area ACT defined by the cell element isolation film 105. The cell conductive line 140 may be formed to intersect with the cell gate structure 110. In this regard, the cell conductive line 140 may act as the bit-line BL.

The cell conductive line 140 may be embodied as a multi-film. The cell conductive line 140 may include, for example, a first cell conductive film 141, a second cell conductive film 142, and/or a third cell conductive film 143. The first to third cell conductive films 141, 142, and/or 143 may be sequentially stacked on the substrate 100 and/or the cell element isolation film 105. Although the cell conductive line 140 is shown to be composed of the three films, the example embodiments not limited thereto.

Each, or one or more, of the first to third cell conductive films 141, 142, and/or 143 may include, for example, at least one of a semiconductor material doped with impurities, a conductive silicide compound, a conductive metal nitride metal, and/or a metal alloy. For example, the first cell conductive film 141 may include a doped semiconductor material, the second cell conductive film 142 may include at least one of the conductive silicide compound and/or the conductive metal nitride, and/or the third cell conductive film 143 may include at least one of metal and metal alloy. However, the example embodiments are not limited thereto.

A bit-line contact 146 may be disposed between the cell conductive line 140 and the substrate 100. That is, the cell conductive line 140 may be formed on the bit-line contact 146. For example, the bit-line contact 146 may be formed at a point where the cell conductive line 140 intersects a center portion of the cell active area ACT having an elongated island shape. The bit-line contact 146 may be formed between the bit-line connection area of the cell active area ACT and the cell conductive line 140.

The bit-line contact 146 may electrically connect the cell conductive line 140 and the substrate 100 to each other. In this regard, the bit-line contact 146 may act as the direct contact DC. The bit-line contact 146 may include, for example, at least one of a semiconductor material doped with impurities, a conductive silicide compound, a conductive metal nitride, and/or a metal.

In FIG. 6, in an area in which the cell conductive line 140 overlaps an upper surface of the bit-line contact 146, the cell conductive line 140 may include the second cell conductive film 142 and/or the third cell conductive film 143. In an area in which the cell conductive line 140 does not overlap the upper surface of the bit-line contact 146, the cell conductive line 140 may include the first to third cell conductive films 141, 142, and/or 143.

In FIG. 6, it is shown that the bit-line contact 146 is not disposed between the cell conductive line 140 closest to the cell area isolation film 22 and a portion of the substrate 100 closest to the cell area isolation film 22. However, the example embodiments are not limited thereto. Alternatively, the bit-line contact 146 may be disposed between the cell conductive line 140 closest to the cell area isolation film 22 and the portion of the substrate 100 closest to the cell area isolation film 22.

The cell line capping film 144 may be disposed on the cell conductive line 140. The cell line capping film 144 may extend in the second direction D2 and along the upper surface of the cell conductive line 140. In this regard, the cell line capping film 144 may include, for example, at least one of silicon nitride, silicon oxynitride, silicon carbonitride, and silicon oxycarbonitride. In a semiconductor memory device according to some example embodiments, the cell line capping film 144 may include, for example, a silicon nitride film. The cell line capping film 144 is shown to be a single film. However, the example embodiments are not limited thereto. Unlike what is illustrated, in some example embodiments, the cell line capping film 144 may have a double layer structure. In some example embodiments, the cell line capping film 144 may have a triple layer structure. In some example embodiments, the cell line capping film 144 may have a quadruple or greater layer structure.

A cell insulating film 130 may be formed on the substrate 100 and/or the cell element isolation film 105. More specifically, the cell insulating film 130 may be formed on the upper surface of the substrate 100 in an area in which the bit-line contact 146 and the storage contact 120 are not formed, and/or on the cell element isolation film 105 and/or the cell area isolation film 22. The cell insulating film 130 may be formed between the substrate 100 and the cell conductive line 140, and/or between the cell element isolation film 105 and the cell conductive line 140.

The cell insulating film 130 may be a single film. However, as illustrated, the cell insulating film 130 may be embodied as a multi-film including a first cell insulating film 131 and a second cell insulating film 132. For example, the first cell insulating film 131 may include a silicon oxide film, while the second cell insulating film 132 may include a silicon nitride film. However, the example embodiments are not limited thereto. Unlike what is illustrated, the cell insulating film 130 may be embodied as a triple film including a silicon oxide film, a silicon nitride film, and/or a silicon oxide film. However, example embodiments are not limited thereto.

A cell buffer film 101 may be disposed between the cell insulating film 130 and the cell area isolation film 22. The cell buffer film 101 may include, for example, a silicon oxide film. However, the example embodiments are not limited thereto.

A cell line spacer 150 may be disposed on a sidewall of each, or one or more, of the cell conductive line 140 and/or the cell line capping film 144. In an area in which the cell conduction line 140 overlaps the bit-line contact 146, the cell line spacer 150 may be formed on the substrate 100 and/or the cell element isolation film 105. The cell line spacer 150 may be disposed on sidewalls of the cell conductive line 140, the cell line capping film 144, and/or the bit-line contact 146.

However, in an area in which the cell conductive line 140 non-overlaps the bit-line contact 146, the cell line spacer 150 may be disposed on the cell insulating film 130.

The cell line spacer 150 may be embodied as a single film. However, as shown, the cell line spacer 150 may have a multi-film structure including first to fourth cell line spacers 151, 152, 153, and/or 154. For example, each, or one or more, of the first to fourth cell line spacers 151, 152, 153, and/or 154 may include one of a silicon oxide film, a silicon nitride film, a silicon oxynitride film (SiON), a silicon oxycarbonitride film (SiOCN), air, and/or a combination thereof. However, example embodiments are not limited thereto.

For example, the second cell line spacer 152 may not be disposed on the cell insulating film 130, but may be disposed on the sidewall of the bit-line contact 146. In FIG. 5 and FIG. 6, the bit-line structure 140ST may extend in an elongate manner in the second direction D2. The cell line spacer 150 may be disposed on a long side wall extending in the second direction D2 among side walls of the bit-line structure 140ST.

In FIG. 6, a dummy bit-line structure 140ST_1 may be disposed on the cell area isolation film 22. The dummy bit-line structure 140ST_1 may have the same structure as that of the bit-line structure 140ST. That is, the dummy bit-line structure 140ST_1 may include the cell conductive line 140 and/or the cell line capping film 144. In this regard, the cell conduction line 140 of the dummy bit-line structure 140ST_1 may be the boundary bit-line BL_IF.

A fence pattern 170 may be disposed on the substrate 100 and/or the cell element isolation film 105. The fence pattern 170 may be formed to overlap the cell gate structure 110 formed in the substrate 100 and/or the cell element isolation film 105. The fence pattern 170 may be disposed between the bit-line structures 140ST extending in the second direction D2. The fence pattern 170 may include, for example, at least one of silicon oxide, silicon nitride, silicon oxynitride, and/or combinations thereof.

The storage contact 120 may be disposed between the cell conductive lines 140 adjacent to each other in the first direction D1. The storage contact 120 may be disposed between fence patterns 170 adjacent to each other in the second direction D2. The storage contact 120 may overlap a portion of the substrate 100 and/or a portion of the cell element isolation film 105 between adjacent cell conductive lines 140. The storage contact 120 may be connected to the storage connection area of the cell active area ACT. In this regard, the storage contact 120 may act as the buried contact BC.

The storage contact 120 may include, for example, at least one of a semiconductor material doped with impurities, a conductive silicide compound, a conductive metal nitride, and/or a metal.

The storage pad 160 may be formed on the storage contact 120. The storage pad 160 may be electrically connected to the storage contact 120. The storage pad 160 may be connected to the storage connection area of the cell active area ACT. In this regard, the storage pad 160 may act as the landing pad LP.

The storage pad 160 may overlap with a portion of an upper surface of the bit-line structure 140ST. The storage pad 160 may include, for example, at least one of a semiconductor material doped with impurities, a conductive silicide compound, a conductive metal nitride, a conductive metal carbide, a metal, and/or a metal alloy.

The pad isolation insulating film 180 may be formed on the storage pad 160 and/or the bit-line structure 140ST. For example, the pad isolation insulating film 180 may be disposed on the cell line capping film 144. The pad isolation insulating film 180 may define the storage pad 160 as each, or one or more, of a plurality of isolated areas. The pad isolation insulating film 180 may not cover an upper surface of the storage pad 160. The pad isolation insulating film 180 may fill the pad isolation recess 180R. The pad isolation recess 180R may isolate adjacent storage pads 160 from each other. The pad isolation insulating film 180 may isolate the storage pads 160 from each other. For example, based on the upper surface of the substrate 100, a vertical level of an upper surface 160U of the storage pad 160 may be equal to a vertical level of an upper surface of the pad isolation insulating film 180.

The pad isolation insulating film 180 may include an insulating material and may electrically isolate adjacent ones of the plurality of storage pads 160 from each other. For example, the pad isolation insulating film 180 may include at least one of a silicon oxide film, a silicon nitride film, a silicon oxynitride film, a silicon oxycarbonitride film, and/or a silicon carbonitride film.

A peripheral element isolation film 26 may be formed in the substrate 100 and/or in the peripheral area 24. The peripheral element isolation film 26 may define a peripheral active area in the peripheral area 24. An upper surface of the peripheral element isolation film 26 is shown as being coplanar with the upper surface of the substrate 100. However, the inventive concepts are not limited thereto. The peripheral element isolation film 26 may include, but is not limited to, at least one of, for example, a silicon oxide film, a silicon nitride film, and/or a silicon oxynitride film.

The peripheral gate structure 240ST may be disposed on the substrate 100 and/or in the peripheral area 24. The peripheral gate structure 240ST may be disposed on the peripheral active area defined by the peripheral element isolation film 26.

The peripheral gate structure 240ST may include a peripheral gate insulating film 230, a peripheral gate conductive film 240, and/or a peripheral capping film 244 sequentially stacked on the substrate 100. The peripheral gate structure 240ST may include a peripheral spacer 245 disposed on a sidewall of the peripheral gate conductive film 240 and/or a sidewall of the peripheral capping film 244.

The peripheral gate conductive film 240 may include first to third peripheral conductive films 241, 242, and/or 243 sequentially stacked on the peripheral gate insulating film 230. In some example embodiments, no additional conductive film may be disposed between the peripheral gate conductive film 240 and the peripheral gate insulating film 230. In some example embodiments, unlike what is illustrated, an additional conductive film, such as a work function conductive film, may be disposed between the peripheral gate conductive film 240 and the peripheral gate insulating film 230.

Although two peripheral gate structures 240ST are shown as being disposed between adjacent peripheral element isolation films 26, this is only for convenience of illustration, and the example embodiments are not limited thereto.

A block conductive structure 240ST_1 may be disposed between the cell area 20 and the peripheral area 24. A portion of the block conductive structure 240ST_1 is shown as overlapping with the cell area isolation film 22. However, the example embodiments are not limited thereto. The block conductive structure 240ST_1 may be a conductive structure closest to the dummy bit-line structure 140ST_1 in the first direction D1.

The block conductive structure 240ST_1 may include a block gate insulating film 230_1, a block conductive line 240_1, and/or a block capping film 244_1 sequentially stacked on the substrate 100. The block conductive structure 240ST_1 may include a block spacer 245_1 disposed on a sidewall of the block conductive line 240_1 and/or a sidewall of the block capping film 244_1. In this regard, the block conductive line 240_1 may be a boundary peripheral gate PR_ST1.

The block conductive line 240_1 may include a first-first to a first-third block conductive films 241_1, 242_1, and/or 243_1 sequentially stacked on the block gate insulating film 230_1. A stacked film structure of the block conductive line 240_1 between the block gate insulating film 230_1 and the block capping film 244_1 may be the same as a stacked film structure of the peripheral gate conductive film 240.

The peripheral gate structure 240ST and the block conductive structure 240ST_1 may be positioned at the same level. In this regard, “A and B being positioned at the same level” may include A and B being formed in the same manufacturing process. Each, or one or more, of the peripheral gate conductive film 240 and/or the block conductive line 240_1 may have the same stacked structure as that of the cell conductive line 140.

The first peripheral conductive film 241 and/or the first-first block conductive film 241_1 may include the same material as that of the first cell conductive film 141. The second peripheral conductive film 242 and/or the first-second block conductive film 242_1 may include the same material as that of the second cell conductive film 142. The third peripheral conductive film 243 and/or the first-third block conductive film 243_1 may include the same material as that of the third cell conductive film 143.

The peripheral gate insulating film 230 and the block gate insulating film 230_1 may include the same material. The peripheral gate insulating film 230 and the block gate insulating film 230_1 may include, for example, silicon oxide, silicon nitride, silicon oxynitride, and/or a high dielectric constant material having a higher dielectric constant than that of silicon oxide.

The peripheral spacer 245 and the block spacer 245_1 may include the same material. For example, the peripheral spacer 245 and the block spacer 245_1 may include at least one of silicon nitride, silicon oxynitride, silicon oxide, silicon carbonitride, silicon oxycarbonitride, and/or combinations thereof. Although each of the peripheral spacer 245 and the block spacer 245_1 is shown as being embodied as a single film, this is only for convenience of illustration and the example embodiments are not limited thereto. In some example embodiments, each, or one or more, of the peripheral spacer 245 and the block spacer 245_1 may be embodied as a stack of multilayers.

The peripheral capping film 244 and the block capping film 244_1 may include the same material. For example, each of the peripheral capping film 244 and the block capping film 244_1 may include at least one of a silicon nitride film, silicon oxynitride, and/or silicon oxide.

A lower etch stop film 250 may be disposed on the substrate 100. The lower etch stop film 250 may be formed according to a profile of the peripheral gate structure 240ST and/or a profile of the block conductive structure 240ST_1. The lower etch stop film 250 may extend along a sidewall of the dummy bit-line structure 140ST_1. For example, the lower etch stop film 250 may include at least one of silicon nitride, silicon oxynitride, silicon carbonitride, and/or silicon oxycarbonitride.

A lower peripheral interlayer insulating film 290 may be disposed on the lower etch stop film 250. The lower peripheral interlayer insulating film 290 may be disposed around the peripheral gate structure 240ST. The lower peripheral interlayer insulating film 290 may be disposed on the cell area isolation film 22 and/or between the dummy bit-line structure 140ST_1 and the block conductive structure 240ST_1.

The lower peripheral interlayer insulating film 290 may include an oxide-based insulating material. An upper surface of the lower peripheral interlayer insulating film 290 may be coplanar with the lower etch stop film 250 extending along an upper surface of the peripheral gate structure 240ST.

An upper peripheral interlayer insulating film 291 is disposed on the peripheral gate structure 240ST and/or the lower peripheral interlayer insulating film 290. The upper peripheral interlayer insulating film 291 may cover the peripheral gate structure 240ST and/or the lower peripheral interlayer insulating film 290. For example, based on the upper surface of the substrate 100, a vertical level of the upper surface of the upper peripheral interlayer insulating film 291 may be the same as a vertical level of an upper surface of the cell line capping film 144.

The upper peripheral interlayer insulating film 291 includes a different material from that of the lower peripheral interlayer insulating film 290. The upper peripheral interlayer insulating film 291 may include, for example, a nitride-based insulating material. For example, the upper peripheral interlayer insulating film 291 may include silicon nitride.

The first peripheral contact plug 260 may be disposed on at least one side of the peripheral gate structure 240ST. For example, the first peripheral contact plug 260 may be disposed on each, or one or more, of both opposing sides of the peripheral gate structure 240ST. The first peripheral contact plug 260 extends through the upper peripheral interlayer insulating film 291 and/or the lower peripheral interlayer insulating film 290 to the substrate 100 of the peripheral area 24. The first peripheral contact plug 260 may be connected to the substrate 100 of the peripheral area 24. The first peripheral wiring pad 265 may be disposed on the upper peripheral interlayer insulating film 291. The first peripheral contact plug 260 and the first peripheral wiring pad 265 may be isolated from each other via a wiring isolation recess 280R. A width of the wiring isolation recess 280R is not limited to what is illustrated and may vary.

Each, or one or more, of the first peripheral contact plug 260 and/or the first peripheral wiring pad 265 may include the same material as that of the storage pad 160. The first peripheral contact plug 260 and/or the first peripheral wiring pad 265 may be formed at the same level as that of the storage pad 160.

An upper surface of the first peripheral contact plug 260 may be coplanar with an upper surface 265U of the first peripheral wiring pad 265. The upper surface 265U of the first peripheral wiring pad 265 may be coplanar with an upper surface 160U of the storage pad 160.

A first interlayer insulating film 296 may be disposed across the cell area 20 and/or the peripheral area 24. The first interlayer insulating film 296 may be disposed on the storage pad 160, the first peripheral contact plug 260, and/or the first peripheral wiring pad 265. The first interlayer insulating film 296 may be disposed on the upper peripheral interlayer insulating film 291.

An upper etch stop layer 295 may be disposed on top of the first interlayer insulating film 296. The upper etch stop layer 295 may be disposed on the pad isolation insulating film 180, the storage pad 160, the first interlayer insulating film 296, the first peripheral contact plug 260, and/or the first peripheral wiring pad 265. The upper etch stop layer 295 may extend along the upper surface of the first interlayer insulating film 296, the upper surface 265U of the first peripheral wiring pad 265, the upper surface of the pad isolation insulating film 180, and/or the upper surface 160U of the storage pad 160. The upper etch stop layer 295 may include, for example, at least one of silicon nitride, silicon oxynitride, silicon carbonitride, and/or silicon boron nitride.

The first interlayer insulating film 296 may fill the wiring isolation recess 280R. In FIG. 5, the first interlayer insulating film 296 may entirely fill the wiring isolation recess 280R. The first interlayer insulating film 296 may include a nitride-based insulating material. The first interlayer insulating film 296 may include, for example, at least one of silicon nitride, silicon carbonitride, silicon carbonitride, and/or silicon boron nitride (SiBN).

The capacitor structure CAP_ST may include the lower electrode 310, an electrode support structure 350 (sometimes referred to as electrode support layers), a capacitor dielectric film 311, and/or an upper electrode 312.

A plurality of lower electrodes 310 may be disposed on the substrate 100. The plurality of lower electrodes 310 may be disposed on a plurality of storage pads 160, respectively. The plurality of lower electrodes 310 may be connected to the plurality of storage pads 160, respectively.

For example, each, or one or more, of the plurality of lower electrodes 310 may have a pillar-shape. The plurality of lower electrodes 310 may extend in an elongate manner in a thickness direction of the substrate 100, that is, a fourth direction D4 perpendicular to each of the first and second directions D1 and D2. A length by which each, or one or more, of the plurality of lower electrodes 310 extends in the thickness direction of the substrate 100 may be larger than a length by which each, or one or more, the plurality of lower electrodes 310 extends in the horizontal direction D1, D2, or D3 parallel to the substrate 100.

For example, the plurality of lower electrodes 310 may be repeatedly arranged along the first direction D1 and the second direction D2. The first direction D1 and the second direction D2 may be orthogonal to each other. However, the example embodiments are not limited thereto. The plurality of lower electrodes 310 may be repeatedly arranged in the first direction D1 to form a row. The rows may be repeatedly arranged in the second direction D2. The plurality of lower electrodes 310 may be repeatedly arranged in the second direction D2 not in a linear manner but in a zigzag manner. The plurality of lower electrodes 310 may be arranged linearly along the third direction D3.

Each, or one or more, of the plurality of lower electrodes 310 may include, but is not limited to, a doped semiconductor material, a conductive metal nitride (such as titanium nitride, tantalum nitride, niobium nitride, or tungsten nitride), a metal (such as ruthenium, iridium, titanium, or tantalum), and/or a conductive metal oxide (such as iridium oxide or niobium oxide). In some example embodiments, each, or one or more, of the plurality of lower electrodes 310 may include titanium nitride (TiN). Furthermore, in some example embodiments, each, or one or more, of the plurality of lower electrodes 310 may include niobium nitride (NbN).

Each, or one or more, of the plurality of lower electrodes 310 may include a first lower electrode 310a and/or a second lower electrode 310b which are disposed on each, or one or more, of the storage pads 160. The first lower electrode 310a and/or the second lower electrode 310b may be spaced apart from each other. For example, the capacitor dielectric film 311, the electrode support structure 350, and/or the upper electrode 312 may be disposed between the first lower electrode 310a and the second lower electrode 310b.

The electrode support structure 350 may include a first support layer 351, a second support layer 352, and/or a third support layer 353. In some example embodiments, the number of support layers included in the electrode support structure 350 is illustrated as being three. However, example embodiments are not limited thereto.

The first support layer 351 may be disposed on the pad isolation insulating film 180. The first support layer 351 may be disposed spaced apart from the pad isolation insulating film 180 and/or the storage pad 160. The first support layer 351 may be disposed between the first and second lower electrodes 310a and 310b adjacent to each other. The first support layer 351 may be in contact with the first and/or second lower electrodes 310a and/or 310b.

The second support layer 352 may be disposed on the first support layer 351. The second support layer 352 may be spaced apart from the first support layer 351. The second support layer 352 may be disposed between the first and second lower electrodes 310a and 310b adjacent to each other. The second support layer 352 may be in contact with the first and second lower electrodes 310a and/or 310b.

The third support layer 353 may be disposed on the second support layer 352. The third support layer 353 may be spaced apart from the first and/or second support layers 351 and 352. The third support layer 353 may be disposed between the first and second lower electrodes 310a and 310b adjacent to each other. The third support layer 353 may be in contact with the first and/or second lower electrodes 310a and/or 310b.

Each, or one or more, of the first to third support layers 351, 352, and/or 353 may include an insulating material. For example, each, or one or more, of the first to third support layers 351, 352, and/or 353 may include at least one of silicon nitride, silicon carbonitride, silicon boron nitride, silicon carbonate, silicon oxynitride, silicon oxide, and/or silicon oxycarbonitride.

The capacitor dielectric film 311 may be formed on the pad isolation insulating film 180, the storage pad 160, the lower electrode 310, and/or the first to third support layers 351, 352, and/or 353. The capacitor dielectric film 311 may extend along a profile of the plurality of lower electrodes 310. The capacitor dielectric film 311 may extend along an upper surface and/or a lower surface of the first support layer 351, an upper surface and/or a lower surface of the second support layer 352, and/or an upper surface and/or a lower surface of the third support layer 353.

The capacitor dielectric film 311 may extend along the pad isolation insulating film 180. Specifically, the capacitor dielectric film 311 may extend along an upper surface of the pad isolation insulating film 180 disposed between the storage pads 160. The capacitor dielectric film 311 may be in direct contact with the upper surface of the pad isolation insulating film 180.

The capacitor dielectric film 311 may include a high-k material including, for example, silicon oxide, silicon nitride, silicon oxynitride, and/or metal. The capacitor dielectric film 311 is illustrated as a single film. However, this is merely for convenience of illustration and the example embodiments are not limited thereto.

In some example embodiments of the semiconductor device, the capacitor dielectric film 311 may include a stack film structure in which a zirconium oxide layer, an aluminum oxide layer, and/or a zirconium oxide layer are sequentially stacked.

In some example embodiments of the semiconductor device, the capacitor dielectric film 311 may include a dielectric film including hafnium (Hf). In some example embodiments of the semiconductor device, the capacitor dielectric film 311 may have a stack film structure of a ferroelectric material film and/or a paraelectric material film.

The ferroelectric material film may have ferroelectric properties. The ferroelectric material film may have a thickness sufficient to have ferroelectric properties. The thickness range of the ferroelectric material film having the ferroelectric properties may vary depending on a type of the ferroelectric material.

For example, the ferroelectric material film may include a monometal oxide. The ferroelectric material film may include a monometal oxide film. In this regard, the monometal oxide may be a binary compound composed of one type of a metal and oxygen. The ferroelectric material film including the monometal oxide may have an orthorhombic crystal system.

In one example, the metal included in the monometal oxide film may be hafnium (Hf). The monometal oxide film may be a hafnium oxide (HfO) film. In this regard, the hafnium oxide film may have a chemical formula that stratifies stoichiometry, or may have a chemical formula that does not satisfies stoichiometry.

In some example embodiments, the metal included in the monometal oxide film may be one of the rare earth metals belonging to the lanthanoids. The monometal oxide film may be a film made of a rare earth metal oxide belonging to the lanthanoids. In this regard, the rare earth metal oxide belonging to the lanthanoids may have a chemical formula that satisfies stoichiometry, or may have a chemical formula that does not satisfy stoichiometry. When the ferroelectric material film includes the monometal oxide film, the ferroelectric material film may have a thickness of, for example, 1 nm inclusive to 10 nm inclusive.

For example, the ferroelectric material film may include a bimetal oxide. The ferroelectric material film may include a bimetal oxide film. In this regard, the bimetal oxide may be a ternary compound composed of two types of metals and oxygen. The ferroelectric material film including the bimetal oxide may have an orthorhombic crystal system.

The metals included in the bimetal oxide film may be, for example, hafnium (Hf) and/or zirconium (Zr). The bimetal oxide film may be a hafnium zirconium oxide film (HfₓZr₍₁₋ₓ)O). In the bimetal oxide film, x may be 0.2 inclusive to 0.8 inclusive. In this regard, the hafnium zirconium oxide film (HfₓZr₍₁₋ₓ₎O) may have a chemical formula that satisfies stoichiometry, or may have a chemical formula that does not satisfy stoichiometry.

When the ferroelectric material film includes a binary metal oxide film, the ferroelectric material film 132 may have a thickness of, for example, 1 nm inclusive to 20 nm inclusive.

For example, the paraelectric material film may be a dielectric film including zirconium (Zr), and/or a stack film including zirconium (Zr). However, the example embodiments are not limited thereto. Even when chemical formulas of dielectric materials are identical with each other, each, or one or more, of the dielectric materials may exhibit ferroelectric properties and/or paraelectric properties depending on a crystal structure of the dielectric material.

The paraelectric material has a positive dielectric constant, and the ferroelectric material may have a negative dielectric constant in a certain range. That is, a paraelectric material has a positive capacitance, and a ferroelectric material may have a negative capacitance.

Generally, when two or more capacitors having positive capacitance are connected in series with each other, a total capacitance thereof decreases. However, when a negative capacitor having a negative capacitance and a positive capacitor having a positive capacitance are connected in series with other, a total capacitance thereof increases.

The upper electrode 312 may be disposed on the capacitor dielectric film 311. The upper electrode 312 may extend along a profile of the capacitor dielectric film 311. The upper electrode 312 may include, but is not limited to, a doped semiconductor material, a conductive metal nitride (such as titanium nitride, tantalum nitride, niobium nitride, or tungsten nitride), a metal (such as ruthenium, iridium, titanium, or tantalum), and/or a conductive metal oxide (such as iridium oxide or niobium oxide).

Although not specifically shown, the upper electrode 312 may have a single-layered or a multi-layered structure. When the upper electrode 312 has the single-layered structure, the upper electrode 312 may include a gapfill layer. The gapfill layer may include silicon germanium (SiGe). When the upper electrode 312 has the multi-layered structure, the upper electrode 312 may include a gapfill layer and/or a low-resistance layer. The gapfill layer may include silicon germanium (SiGe), and/or the low-resistance layer may include tungsten nitride (WN). The gapfill layer may fill a narrow gap between the lower electrodes 310 such that a void is absent. The low-resistance layer may lower resistance of the upper electrode 312.

The cell metal contact 460b may be disposed on the capacitor structure CAP_ST. The cell metal contact 460b may be disposed on the upper electrode 312 and may be in contact with an upper surface 312U of the upper electrode 312.

A cell metal line 465b may be formed on the cell metal contact 460b. The cell metal line 465b may be in contact with the cell metal contact 460b. The cell metal contact 460b may connect the upper electrode 312 and the cell metal line 465b to each other.

A second interlayer insulating film 381 may be disposed on the storage pad 160, the pad isolation insulating film 180, the first peripheral wiring pad 265, and/or the first interlayer insulating film 296. The second interlayer insulating film 381 may be disposed on the upper etch stop layer 295. The second interlayer insulating film 381 extends on the cell area isolation film 22 so as to contact a sidewall of the upper electrode 312. The first capacitor dielectric film 311 may extend along a boundary between the pad isolation insulating film 180 and the second interlayer insulating film 381. The second interlayer insulating film 381 may include, for example, an oxide-based insulating material. However, the example embodiments are not limited thereto.

The second peripheral contact plug 360 may be formed within the second interlayer insulating film 381. The second peripheral contact plug 360 may extend through the second interlayer insulating film 381 and/or the upper etch stop layer 295 in the fourth direction D4. The second peripheral contact plug 360 may be connected to the first peripheral wiring pad 265 of the peripheral area 24.

The second peripheral contact plug 360 may include a peripheral contact plug trench 360T, a barrier layer 360m1, and/or a conductive layer 360m2.

The peripheral contact plug trench 360T may extend in the second interlayer insulating film 381 in the fourth direction D4 so as to expose an upper surface 265U of the first peripheral wiring pad 265. The barrier layer 360m1 may be disposed on a sidewall and/or a bottom surface of the peripheral contact plug trench 360T. The conductive layer 360m2 may fill the peripheral contact plug trench 360T while being disposed on the barrier layer 360m1.

Each, or one or more, of the barrier layer 360m1 and/or the conductive layer 360m2 may include a conductive material. For example, the barrier layer 360m1 may include titanium nitride (TiN), and the conductive layer 360m2 may include tungsten (W). However, the example embodiments are not limited thereto.

The second peripheral wiring pads 365 may be spaced apart from each other and may be disposed on the second peripheral contact plugs 360, respectively. The second peripheral wiring pad 365 may be connected to the second peripheral contact plug 360. A lower surface 365L of the second peripheral wiring pad 365 may be in contact with an upper surface 381U of the second interlayer insulating film 381.

A third interlayer insulating film 481 may be disposed on the upper electrode 312 and/or the second interlayer insulating film 381 in the cell area 20 and be in contact with each, or one or more, of the upper surface 312U of the upper electrode 312 and/or the upper surface 381U of the second interlayer insulating film 381. In the fourth direction D4, the upper surface 312U of the upper electrode 312 and the upper surface 381U of the second interlayer insulating film 381 may be coplanar with each other. The third interlayer insulating film 481 may include, for example, an oxide-based insulating material. However, the example embodiments are not limited thereto.

The third interlayer insulating film 481 may be disposed on the second interlayer insulating film 381 in the peripheral area 24. The second peripheral wiring pad 365 may be formed in the third interlayer insulating film 481. The lower surface 365L of the second peripheral wiring pad 365 may be in contact with a lower surface 481L of the third interlayer insulating film 481.

The peripheral metal contact 460a may be formed within the third interlayer insulating film 481 and/or on the second peripheral wiring pad 365. The peripheral metal contact 460a is connected to the second peripheral wiring pad 365.

The peripheral metal line 465a may be formed on the peripheral metal contact 460a. The peripheral metal line 465a may be in contact with the peripheral metal contact 460a. The peripheral metal contact 460a may connect the second peripheral wiring pad 365 and the peripheral metal line 465a to each other.

In the fourth direction D4, the second peripheral wiring pad 365 may be positioned at the same vertical level as a vertical level of the upper surface 312U of the upper electrode 312. The lower surface 365L of the second peripheral wiring pad 365, which is in contact with the second peripheral contact plug 360, may be positioned at the same vertical level as a vertical level of the upper surface 312U of the upper electrode 312. The lower surface 365L of the second peripheral wiring pad 365 may be coplanar with the upper surface 312U of the upper electrode 312. The upper surface 365U of the second peripheral wiring pad 365 may be positioned at a higher vertical level than a vertical level of the upper surface 381U of the second interlayer insulating film 381.

In the fourth direction D4, a bottom surface CAP_STL of the capacitor structure CAP_ST may be positioned at the same vertical level as a vertical level of the upper surface 265U of the first peripheral wiring pad 265.

A thickness T1 in the fourth direction D4 of the cell metal contact 460b may be equal to a sum of the thickness T21 in the fourth direction D4 of the second peripheral wiring pad 365 and a thickness T22 in the fourth direction D4 of the peripheral metal contact 460a. In the fourth direction D4, the upper surface 460aU of the peripheral metal contact 460a and the upper surface 460bU of the cell metal contact 460b may be positioned at the same vertical level.

In the fourth direction D4, a distance T3 from the upper surface 160U of the storage pad 160 to the upper surface 312U of the upper electrode 312 may be equal to a distance T4 from the upper surface 265U of the first peripheral wiring pad 265 to the lower surface 365L of the second peripheral wiring pad 365. The distance T4 from the upper surface 265U of the first peripheral wiring pad 265 to the lower surface 365L of the second peripheral wiring pad 365 may be equal to a thickness of the second peripheral contact plug 360.

In the fourth direction D4, a distance T1 from the lower surface 481L of the third interlayer insulating film 481 to the upper surface 460bU of the cell metal contact 460b may be equal to a distance (a sum of T21 and T22) from the lower surface 481L of the third interlayer insulating film 481 to the upper surface 460aU of the peripheral metal contact 460a.

A length T4 by which the second peripheral contact plug 360 extends from the peripheral area 24 in the fourth direction D4 may be larger than a length T5 by which the lower electrode 310 extends from the cell area 20 in the fourth direction D4.

In the fourth direction D4, the distance T1 from the upper surface 312U of the upper electrode 312 to the upper surface 460bU of the cell metal contact 460b may be equal to a distance (a sum of T21 and T22) from the lower surface 365L of the second peripheral wiring pad 365 to the upper surface 460aU of the peripheral metal contact 460a.

In the fourth direction D4, the distance T3 from the lower surface 481L of the third interlayer insulating film 481 of the cell area 20 to the bottom surface of the lower electrode 310 may be equal to the distance T4 from the lower surface 481L of the third interlayer insulating film 481 of the peripheral area 24 to the bottom surface of the second peripheral contact plug 360.

In the fourth direction D4, the distance from the upper surface 295U of the etch stop layer 295 of the cell area 20 to the upper surface 312U of the upper electrode 312 may be equal to a distance from the upper surface 295U of the etch stop layer 295 of the peripheral area 24 to the upper surface 381U of the second interlayer insulating film 381.

In the fourth direction D4, a distance from the upper surface 295U of the etch stop layer 295 of the cell area 20 to the upper surface 312U of the upper electrode 312 may be equal to a distance from the upper surface 295U of the etch stop layer 295 of the peripheral area 24 to the lower surface 365L of the second peripheral wiring pad 365.

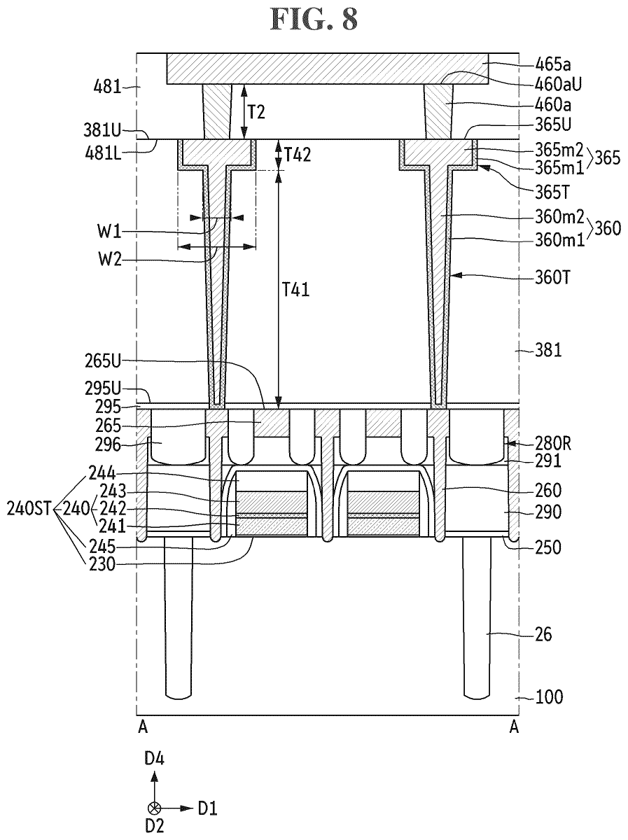

FIG. 8 is a cross-sectional view illustrating a semiconductor memory device according to some example embodiments, and is a diagram corresponding to FIG. 5. For convenience of description, following descriptions will focus on differences thereof from those described above using FIG. 1 to FIG. 7.

Referring to FIG. 8, the second peripheral contact plug 360 may include a peripheral contact plug trench 360T, a first barrier layer 360m1, and/or a first conductive layer 360m2. The second peripheral wiring pad 365 may include a peripheral wiring trench 365T, a second barrier layer 365m1, and/or a second conductive layer 365m2.

The peripheral contact plug trench 360T may extend in the fourth direction D4 within the second interlayer insulating film 381 so as to expose the upper surface 265U of the first peripheral wiring pad 265. The first barrier layer 360m1 may be disposed on a sidewall and/or a bottom surface of the peripheral contact plug trench 360T. The first conductive layer 360m2 may fill the peripheral contact plug trench 360T while being disposed on the first barrier layer 360m1.

Each, or one or more, of the first barrier layer 360m1 and/or the first conductive layer 360m2 may include a conductive material. For example, the first barrier layer 360m1 may include titanium nitride (TiN), and the first conductive layer 360m2 may include tungsten (W). However, the example embodiments are not limited thereto.

The peripheral wiring trench 365T may be disposed on the peripheral contact plug trench 360T. The peripheral wiring trench 365T may extend in the fourth direction D4 within the second interlayer insulating film 381. The second barrier layer 365m1 may be disposed on a sidewall and/or a bottom surface of the peripheral wiring trench 365T. The second conductive layer 365m2 may fill the peripheral wiring trench 365T while being disposed on the second barrier layer 365m1.

In the first direction D1, a width W2 of the peripheral wiring trench 365T may be larger than a width W1 of the peripheral contact plug trench 360T. However, the example embodiments are not limited thereto.

Each, or one or more, of the second barrier layer 365m1 and/or the second conductive layer 365m2 may include a conductive material. For example, the second barrier layer 365m1 may include titanium nitride (TiN), and the second conductive layer 365m2 may include tungsten (W). However, the example embodiments are not limited thereto.

In the fourth direction D4, the upper surface 365U of the second peripheral wiring pad 365 may be positioned at the same vertical level as a vertical level of the upper surface 312U of the upper electrode 312. The upper surface 365U of the second peripheral wiring pad 365 may be coplanar with the upper surface 381U of the second interlayer insulating film 381.

In the fourth direction D4, the thickness T1 of the cell metal contact 460b may be equal to the thickness T2 of the peripheral metal contact 460a.

In the fourth direction D4, the distance T3 from the upper surface 160U of the storage pad 160 to the upper surface 312U of the upper electrode 312 may be equal to the distance from the upper surface 265U of the first peripheral wiring pad 265 to the upper surface 365U of the second peripheral wiring pad 365. The distance from the upper surface 265U of the first peripheral wiring pad 265 to the upper surface 365U of the second peripheral wiring pad 365 may be equal to a sum of a thickness T41 of the second peripheral contact plug 360 and a thickness T42 of the second peripheral wiring pad 365.

In the fourth direction D4, the distance T1 from the lower surface 481L of the third interlayer insulating film 481 to the upper surface 460bU of the cell metal contact 460b may be equal to the distance T2 from the lower surface 481L of the third interlayer insulating film 481 to the upper surface 460aU of the peripheral metal contact 460a.

The length T41 by which the second peripheral contact plug 360 extends from the peripheral area 24 in the fourth direction D4 may be larger than the length T5 by which the lower electrode 310 extends from the cell area 20 in the fourth direction D4.

In the fourth direction D4, the distance T1 from the upper surface 312U of the upper electrode 312 to the upper surface 460bU of the cell metal contact 460b may be equal to the distance T2 from the upper surface 365U of the second peripheral wiring pad 365 to the upper surface 460aU of the peripheral metal contact 460a.

In the fourth direction D4, the distance T3 from the lower surface 481L of the third interlayer insulating film 481 of the cell area 20 to the bottom surface of the lower electrode 310 may be equal to a distance (a sum of T41 and T42) from the lower surface 481L of the third interlayer insulating film 481 of the peripheral area 24 to the bottom surface of the second peripheral contact plug 360.

In the fourth direction D4, the distance from the upper surface 295U of the etch stop layer 295 of the cell area 20 to the upper surface 312U of the upper electrode 312 may be equal to the distance from the upper surface 295U of the etch stop layer 295 of the peripheral area 24 to the upper surface 381U of the second interlayer insulating film 381.

In the fourth direction D4, the distance from the upper surface 295U of the etch stop layer 295 of the cell area 20 to the upper surface 312U of the upper electrode 312 may be equal to the distance from the upper surface 295U of the etch stop layer 295 of the peripheral area 24 to the upper surface 365U of the second peripheral wiring pad 365.

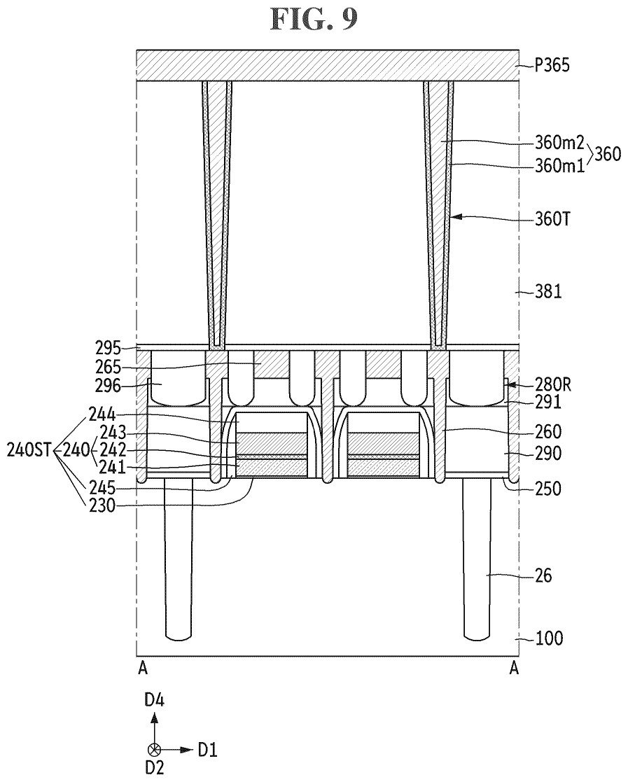

FIGS. 9 to 14 are diagrams of intermediate structures corresponding to intermediate steps of a method of manufacturing a semiconductor memory device according to some example embodiments. Contents duplicate with those described using FIGS. 1 to 7 are briefly described or the descriptions thereof are omitted.

For reference, FIGS. 9 to 14 are diagrams for illustrating a method of manufacturing the semiconductor memory device as illustrated in FIGS. 1 to 7.

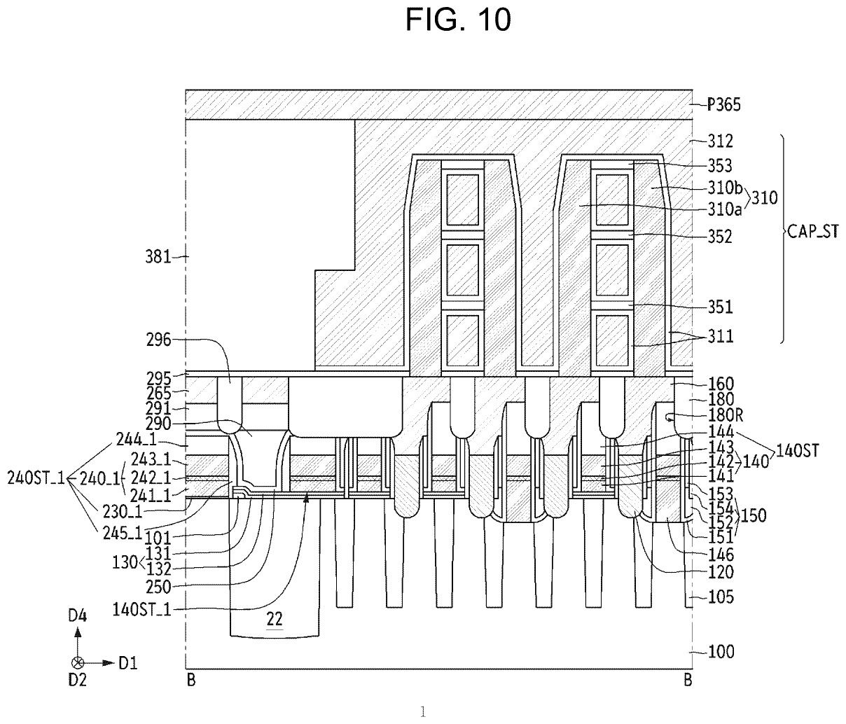

Referring to FIGS. 9 and 10, the capacitor structure CAP_ST is formed first, and then the second peripheral contact plug 360 is formed.

First, a planarization process is performed on the upper surface of the upper electrode 312 and/or the upper surface of the second interlayer insulating film 381. The planarization process may be, for example, a CMP (Chemical Mechanical Polishing) process. Accordingly, the upper surface of the upper electrode 312 and/or the upper surface of the second interlayer insulating film 381 may be coplanar with each other.

Thereafter, the peripheral contact plug trench 360T is formed in the second interlayer insulating film 381 of the peripheral area 24 so as to extend through the second interlayer insulating film 381 in the fourth direction D4. The peripheral contact plug trench 360T may expose the upper surface 265U of the first peripheral wiring pad 265. The barrier layer 360m1 and the conductive layer 360m2 are sequentially formed in the peripheral contact plug trench 360T. The second peripheral contact plug 360 may be connected to the first peripheral wiring pad 265.

Afterwards, a pre-second peripheral wiring pad P365 is formed on the second peripheral contact plug 360, the second interlayer insulating film 381, and/or the upper electrode 312. The pre-second peripheral wiring pad P365 may be formed integrally with the cell area 20, the cell area isolation film 22, and/or the peripheral area 24. The pre-second peripheral wiring pad P365 may be disposed on the second peripheral contact plug 360 in the peripheral area 24, and/or on the upper electrode 312 in the cell area 20.

Although not specifically illustrated, the pre-second peripheral wiring pad P365 may include a barrier layer (not shown) and/or a conductive layer (not shown) on the barrier layer (not shown). For example, the barrier layer (not shown) may include titanium nitride, and the conductive layer (not shown) may include tungsten. However, the example embodiments are not limited thereto.

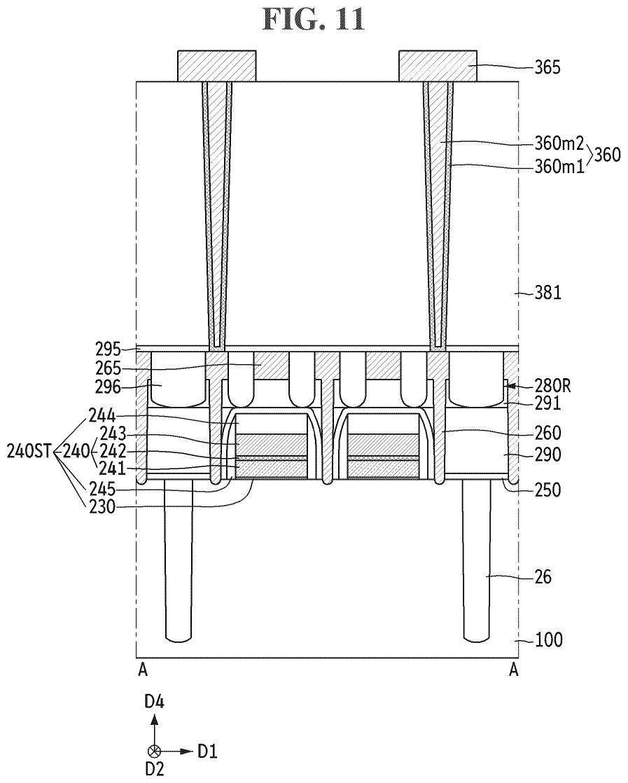

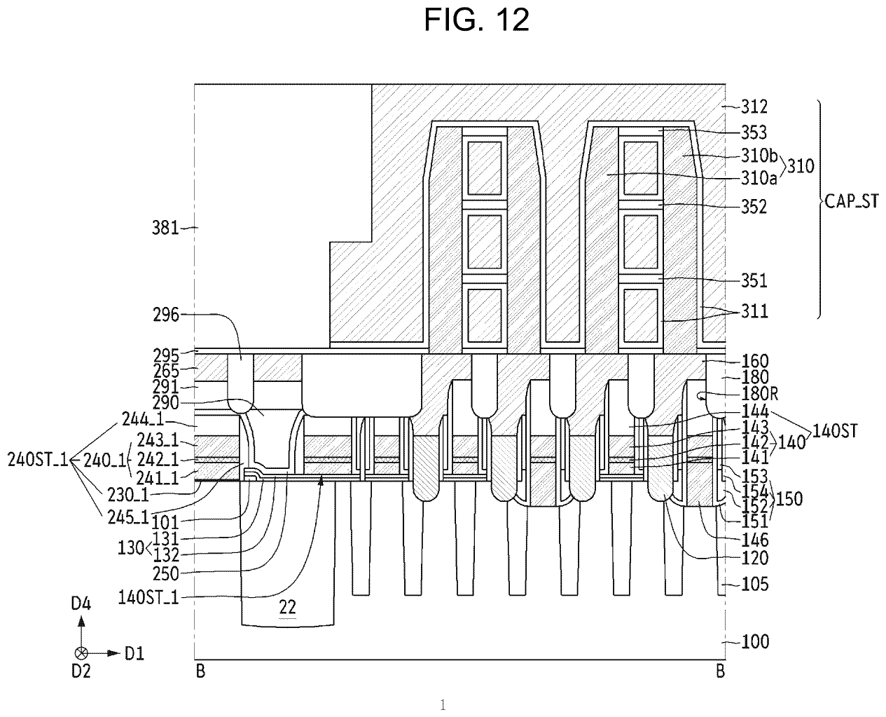

Thereafter, referring to FIG. 11 and FIG. 12, the second peripheral wiring pad 365 may be formed on the second peripheral contact plug 360. The pre-second peripheral wiring pad P365 of the cell area 20 may be reduced, or removed, to expose the upper surface of the upper electrode 312. The pre-second peripheral wiring pad P365 of the peripheral area 24 may be patterned using a photo process to form the second peripheral wiring pad 365.

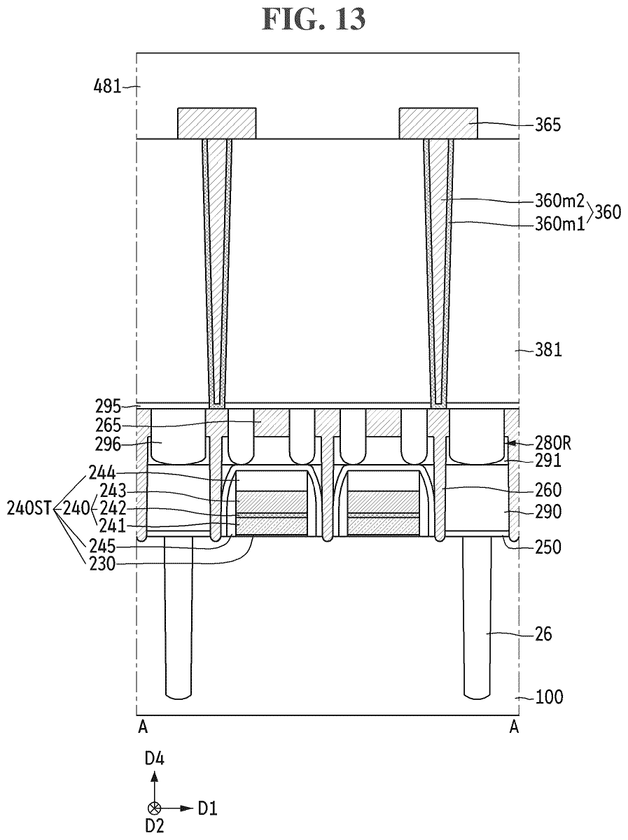

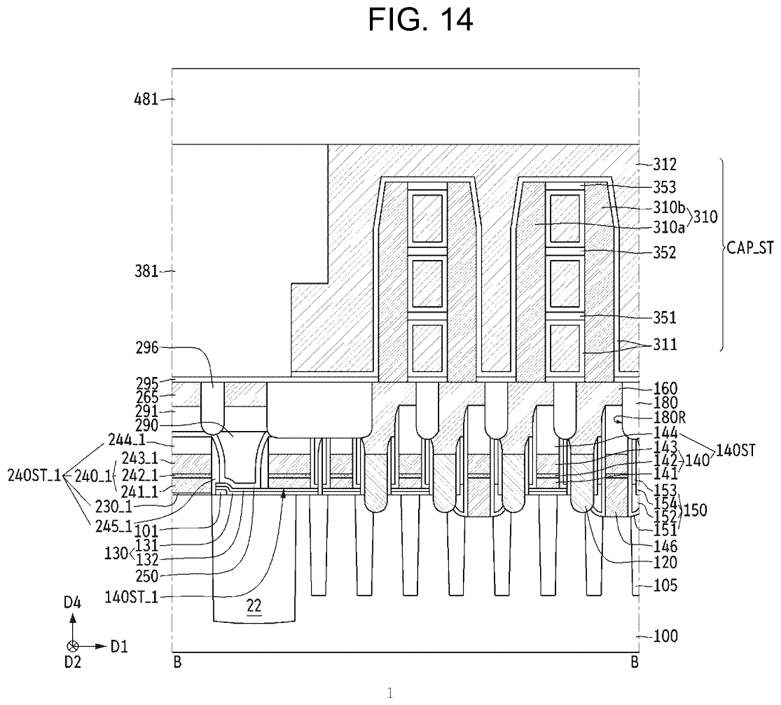

Thereafter, referring to FIG. 13 and FIG. 14, the third interlayer insulating film 481 is formed on the cell area 20 and/or the peripheral area 24. In the cell area 20, the third interlayer insulating film 481 may be formed to cover the upper surface of the upper electrode 312 and/or the upper surface of the second interlayer insulating film 381. In the peripheral area 24, the third interlayer insulating film 481 may be formed to cover the upper surface of the second interlayer insulating film 381, and/or the upper surface and/or side surface of the second peripheral wiring pad 365.

Afterwards, referring to FIG. 5 and FIG. 6, the cell metal contact 460b may be formed in the third interlayer insulating film 481 of the cell area 20, and the peripheral metal contact 460a may be formed in the third interlayer insulating film 481 of the peripheral area 24.

The peripheral metal line 465a may be formed on the peripheral metal contact 460a, and the cell metal line 465b may be formed on the cell metal contact 460b, so that the semiconductor memory device of FIG. 5 and FIG. 6 may be formed. The peripheral metal contact 460a may connect the second peripheral wiring pad 365 and the peripheral metal line 465a to each other. The cell metal contact 460b may connect the upper electrode 312 and the cell metal line 465b to each other.

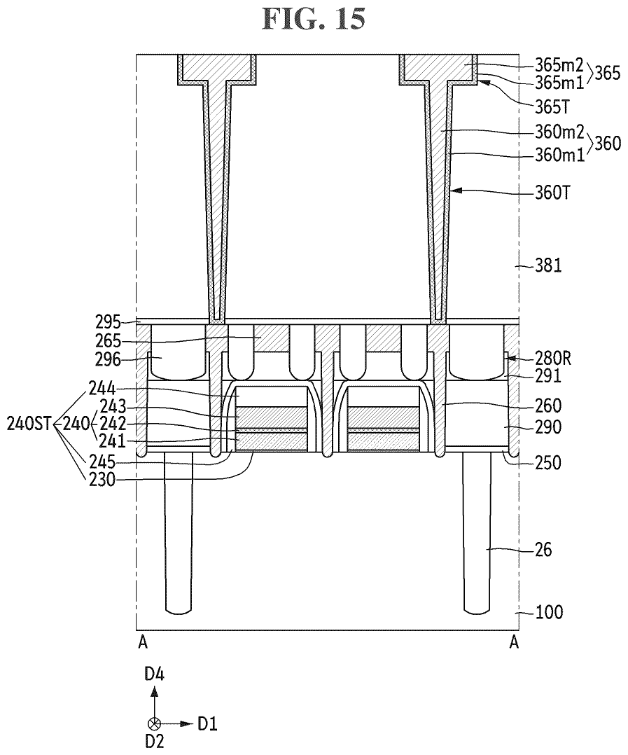

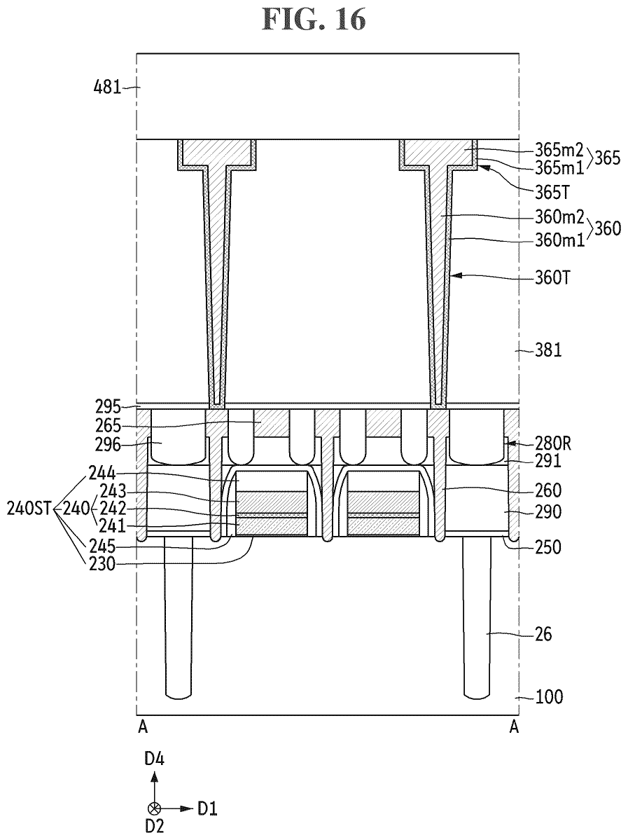

FIGS. 15 to 16 are diagrams of intermediate structures corresponding to intermediate steps of a method of manufacturing a semiconductor memory device according to some example embodiments. Contents duplicate with those described above using FIGS. 9 to 14 are briefly described or descriptions thereof are omitted.

For reference, FIGS. 15 to 16 are diagrams for illustrating a method of manufacturing the semiconductor memory device as illustrated in FIG. 8.

Referring to FIG. 15, the peripheral contact plug trench 360T and/or the peripheral wiring trench 365T extending in a fourth direction D4 are formed within the second interlayer insulating film 381 of the peripheral area 24. The peripheral contact plug trench 360T may expose an upper surface of the first peripheral wiring pad 265. Each, or one or more, of the first barrier layer 360m1 and/or the second barrier layer 365m1 is formed on a sidewall and/or a bottom surface of each, or one or more, of the peripheral contact plug trench 360T and/or the peripheral wiring trench 365T. On each, or one or more, of the first barrier layer 360m1 and/or the second barrier layer 365m1, each, or one or more, of the first conductive layer 360m2 and/or the second conductive layer 365m2 are formed to fill each, or one or more, of the peripheral contact plug trench 360T and/or the peripheral wiring trench 365T.

The first barrier layer 360m1 and the second barrier layer 365m1 may be formed integrally and in the same process. The first conductive layer 360m2 and the second conductive layer 365m2 may be formed integrally and in the same process.

Thus, the peripheral contact plug 360 and/or the second peripheral wiring pad 365 are formed in the second interlayer insulating film 381. The peripheral contact plug 360 and/or the second peripheral wiring pad 365 may be connected to the first peripheral wiring pad 265.

Thereafter, referring to FIG. 16, FIG. 6, and FIG. 8, the third interlayer insulating film 481 is formed on the cell area 20 and/or the peripheral area 24. In the cell area 20, the third interlayer insulating film 481 may be formed to cover the upper surface of the upper electrode 312 and/or the upper surface of the second interlayer insulating film 381. In the peripheral area 24, the third interlayer insulating film 481 may be formed to cover the upper surface of the second interlayer insulating film 381 and/or the upper surface of the second peripheral wiring pad 365.

Afterwards, the cell metal contact 460b may be formed in the third interlayer insulating film 481 of the cell area 20, and the peripheral metal contact 460a may be formed in the third interlayer insulating film 481 of the peripheral area 24.

The peripheral metal line 465a may be formed on the peripheral metal contact 460a, and the cell metal line 465b may be formed on the cell metal contact 460b, so that the semiconductor memory device of FIG. 8 may be formed.

According to the semiconductor memory manufacturing method according to some example embodiments, the vertical level of the upper and/or lower surface of the second peripheral wiring pad 365 may be equal to a vertical level of an upper surface of the upper electrode 312, and a height and a vertical level of the peripheral metal contact 460a may be equal to a height and/or a vertical level of the cell metal contact 460b. Accordingly, the thickness of the upper electrode 312 may be reduced, and the warpage of the peripheral metal contact 460a may be suppressed. Furthermore, since the capacitor structure CAP_ST is formed first and then the second peripheral contact plug 360 and the second peripheral wiring pad 365 are formed, influence of the capacitor structure CAP_ST formation process may be minimized in forming the second peripheral contact plug 360 and the second peripheral wiring pad 365.

Although some example embodiments of the inventive concepts have been described with reference to the accompanying drawings, the inventive concepts are not limited to example embodiments, but may be implemented in various different forms. A person skilled in the art may appreciate that the inventive concepts may be practiced in other concrete forms without changing the technical spirit or essential characteristics of the inventive concepts. Therefore, it should be appreciated that the embodiments as described above is not restrictive but illustrative in all, or one or more, respects.

What is claimed is:

1. A semiconductor memory device comprising:
a substrate extending in first and second directions intersecting each other, the substrate including a cell area and a peripheral area around the cell area;
a storage pad on the cell area;
a capacitor structure including a lower electrode electrically connected to the storage pad, a capacitor dielectric film extending along the lower electrode, and an upper electrode on the capacitor dielectric film;
a cell metal contact on the upper electrode and contacting an upper surface of the upper electrode;
a peripheral gate structure on the peripheral area;
a first peripheral contact plug on at least one side of the peripheral gate structure and electrically connected to the substrate;
a first peripheral wiring pad in a first interlayer insulating film on the storage pad and the first peripheral contact plug;
a second peripheral contact plug extending through a second interlayer insulating film on the first interlayer insulating film in a third direction perpendicular to each of the first direction and the second direction, wherein the second peripheral contact plug is electrically connected to the first peripheral wiring pad;
a second peripheral wiring pad on the second peripheral contact and contacting the second peripheral contact plug; and
a peripheral metal contact in a third interlayer insulating film on the second peripheral wiring pad, wherein the peripheral metal contact is electrically connected to the second peripheral wiring pad,
wherein in the third direction, the second peripheral wiring pad has a surface having a vertical level equal to a vertical level of the upper surface of the upper electrode, and
wherein a vertical level of a bottom surface of the capacitor structure is equal to a vertical level of an upper surface of the first peripheral wiring pad.

2. The semiconductor memory device of claim 1, wherein in the third direction, a vertical level of a lower surface of the second peripheral wiring pad is equal to the vertical level of the upper surface of the upper electrode.

3. The semiconductor memory device of claim 1, wherein in the third direction, a vertical level of an upper surface of the second peripheral wiring pad is equal to the vertical level of the upper surface of the upper electrode.

4. The semiconductor memory device of claim 1, wherein a thickness of the cell metal contact is equal to a sum of a thickness of the second peripheral wiring pad and a thickness of the peripheral metal contact.

5. The semiconductor memory device of claim 1, wherein a thickness of the cell metal contact is equal to a thickness of the peripheral metal contact.

6. The semiconductor memory device of claim 1, wherein in the third direction, a vertical level of an upper surface of the cell metal contact is equal to a vertical level of an upper surface of the peripheral metal contact.

7. The semiconductor memory device of claim 1, wherein in the third direction, a distance from an upper surface of the storage pad to an upper surface of the upper electrode is equal to a distance from an upper surface of the first peripheral wiring pad to a lower surface of the second peripheral wiring pad.

8. The semiconductor memory device of claim 7, wherein the distance from the upper surface of the first peripheral wiring pad to the lower surface of the second peripheral wiring pad is equal to a thickness of the second peripheral contact plug.

9. The semiconductor memory device of claim 1, wherein in the third direction, a distance from an upper surface of the storage pad to an upper surface of the upper electrode is equal to a distance from an upper surface of the first peripheral wiring pad to an upper surface of the second peripheral wiring pad.

10. The semiconductor memory device of claim 9, wherein the distance from the upper surface of the first peripheral wiring pad to the upper surface of the second peripheral wiring pad is equal to a sum of a thickness of the second peripheral contact plug and a thickness of the second peripheral wiring pad.

11. A semiconductor memory device comprising:
a substrate including a cell area and a peripheral area around the cell area, wherein the cell area includes an active area defined by an element isolation film;
a storage pad on the cell area and electrically connected to the active area;
a capacitor structure including a lower electrode electrically connected to the storage pad, electrode support layers supporting the lower electrode, a capacitor dielectric film extending along the lower electrode, and an upper electrode on the capacitor dielectric film;
a cell metal contact on the upper electrode and contacting an upper surface of the upper electrode;
a peripheral gate structure on the peripheral area;
a first peripheral contact plug on each of both opposing sides of the peripheral gate structure and electrically connected to the substrate;
a first peripheral wiring pad in a first interlayer insulating film on the storage pad and the first peripheral contact plug, wherein a vertical level of the first peripheral wiring pad is equal to a vertical level of the storage pad;
a second peripheral contact plug vertically extending through a second interlayer insulating film on the first interlayer insulating film, wherein the second peripheral contact plug is electrically connected to the first peripheral wiring pad;
a second peripheral wiring pad on the second peripheral contact plug and electrically connected to the second peripheral contact plug, wherein the second peripheral wiring pad contacts an upper surface of the second interlayer insulating film;
a peripheral metal contact on the second peripheral wiring pad and electrically connected to the second peripheral wiring pad; and
a third interlayer insulating film on the upper electrode and the second interlayer insulating film and contacting each of the upper surface of the upper electrode and an upper surface of the second interlayer insulating film,
wherein in the vertical direction, the upper surface of the upper electrode and the upper surface of the second interlayer insulating film are coplanar,
wherein a distance from a lower surface of the third interlayer insulating film to an upper surface of the cell metal contact is equal to a distance from a lower surface of the third interlayer insulating film to an upper surface of the peripheral metal contact, and
wherein a length of the second peripheral contact plug is larger than a length of the lower electrode.

12. The semiconductor memory device of claim 11, wherein in the vertical direction, a lower surface of the second peripheral wiring pad is coplanar with the upper surface of the upper electrode.

13. The semiconductor memory device of claim 11, wherein in the vertical direction, an upper surface of the second peripheral wiring pad is coplanar with the upper surface of the second interlayer insulating film.

14. The semiconductor memory device of claim 11, wherein a distance from the upper surface of the upper electrode to an upper surface of the cell metal contact is equal to a distance from a lower surface of the second peripheral wiring pad to the upper surface of the peripheral metal contact.

15. The semiconductor memory device of claim 11, wherein a distance from the upper surface of the upper electrode to an upper surface of the cell metal contact is equal to a distance from an upper surface of the second peripheral wiring pad to the upper surface of the peripheral metal contact.

16. The semiconductor memory device of claim 11, wherein the second peripheral contact plug includes:
a peripheral contact plug trench extending in the vertical direction within the second interlayer insulating film and exposing an upper surface of the first peripheral wiring pad;
a barrier layer on a sidewall and a bottom surface of the peripheral contact plug trench; and
a conductive layer on the barrier layer.

17. The semiconductor memory device of claim 11, wherein the second peripheral contact plug includes:
a peripheral contact plug trench extending in the vertical direction within the second interlayer insulating film and exposing an upper surface of the first peripheral wiring pad;
a first barrier layer on a side wall and a bottom surface of the peripheral contact plug trench; and
a first conductive layer on the first barrier layer,
wherein the second peripheral wiring pad includes:
a peripheral wiring trench on the peripheral contact plug trench and extending in the vertical direction within the second interlayer insulating film;
a second barrier layer within the peripheral wiring trench; and
a second conductive layer on the second barrier layer.

18. A semiconductor memory device comprising:
a substrate including a cell area and a peripheral area around the cell area, wherein the cell area includes an active area defined by an element isolation film;
a bit line structure on the cell area and including a cell conductive line and a cell line capping film on the cell conductive line;
a cell gate electrode in the cell area of the substrate and intersecting the cell conductive line;
a storage pad on a side surface of the bit line structure and on the cell area, wherein the storage pad is electrically connected to the active area;
a capacitor structure including a lower electrode electrically connected to the storage pad, electrode support layers supporting the lower electrode, a capacitor dielectric film extending along the lower electrode, and an upper electrode on the capacitor dielectric film;
a cell metal contact on the capacitor structure and contacting an upper surface of the upper electrode;
a peripheral gate structure on the peripheral area;
a first peripheral contact plug on each of opposing sides of the peripheral gate structure and electrically connected to the substrate;
a first peripheral wiring pad in a first interlayer insulating film, wherein the first interlayer insulating film is on the storage pad and the first peripheral contact plug;
an etch stop layer on the storage pad and the first peripheral wiring pad;
a second peripheral contact plug extending in a vertical direction within a second interlayer insulating film on the etch stop layer, wherein the second peripheral contact plug is electrically connected to the first peripheral wiring pad;
a second peripheral wiring pad on the second peripheral contact plug and electrically connected to the second peripheral contact plug, wherein the second peripheral wiring pad contacts an upper surface of the second interlayer insulating film;
a peripheral metal contact on the second peripheral wiring pad and electrically connected to the second peripheral wiring pad; and
a third interlayer insulating film on the upper electrode and the second interlayer insulating film, the third interlayer insulating film contacting each of the upper surface of the upper electrode and the upper surface of the second interlayer insulating film,
wherein a distance from a lower surface of the third interlayer insulating film at the cell area to a bottom surface of the lower electrode is equal to a distance from a lower surface of the third interlayer insulating film of the peripheral area to a bottom surface of the second peripheral contact plug,
wherein a distance from an upper surface of the etch stop layer of the cell area to the upper surface of the upper electrode is equal to a distance from an upper surface of the etch stop layer at the peripheral area to the upper surface of the second interlayer insulating film, and
wherein in the vertical direction, the second peripheral wiring pad has a surface having a vertical level equal to a vertical level of the upper surface of the upper electrode.

19. The semiconductor memory device of claim 18, wherein a distance from an upper surface of the etch stop layer at the cell area to the upper surface of the upper electrode is equal to a distance from an upper surface of the etch stop layer at the peripheral area to a lower surface of the second peripheral wiring pad.

20. The semiconductor memory device of claim 18, wherein a distance from an upper surface of the etch stop layer at the cell area to the upper surface of the upper electrode is equal to a distance from an upper surface of the etch stop layer at the peripheral area to an upper surface of the second peripheral wiring pad.
